(19) United States
(12) Patent Application Publication
(10) Pub. No.: US 2025/0324776 A1
(43) Pub. Date: Oct. 16, 2025

(54) LIGHT DETECTOR HAVING AN ARRAY OF LIGHT ABSORPTION MATERIAL

(71) Applicant: TEXAS INSTRUMENTS INCORPORATED, Dallas, TX (US)

(72) Inventors: Sarvagya Dwivedi, Heverlee (BE); Gerd Schuppener, Allen, TX (US); Yogesh Ramadass, San Jose, CA (US)

(21) Appl. No.: 18/636,149

(22) Filed: Apr. 15, 2024

(51) Int. Cl. H01L 31/107; H01L 31/02

(52) U.S. Cl. CPC H10F 30/2255; H10F 77/959

(57) ABSTRACT

A device includes a semiconductor substrate having a surface. The device includes a first region in the substrate having a first dopant, a second region in the substrate having a second dopant, and a third region in the substrate having the first dopant. A first light absorption layer is on the surface and over a fourth region of the substrate between the first and second regions. The first light absorption layer is configured to absorb light of a particular wavelength. A second light absorption layer is on the surface and over a fifth region of the substrate between the second and third regions. The second light absorption layer is configured to absorb the light of the particular wavelength. At least one of lateral dimensions of the first and second light absorption layers or a lateral separation between the first and second light absorption layers is based on the particular wavelength.

### BACKGROUND

A free space light detector can include a light absorption layer in which electron-hole pairs can be created as a result of photons of light entering the absorption layer. A light absorption layer may be fabricated as a thin film material, but the thickness of the light absorption layer may be substantially less than the wavelength of light to which the free space light detector is intended to be sensitive. Accordingly, the absorption layer may not be able to absorb a significant amount of light thereby causing the free space light detector to have a low responsivity.

### SUMMARY

In one example, a semiconductor device includes a semiconductor substrate having a surface. The semiconductor device includes a first region in the semiconductor substrate having a first dopant, a second region in the semiconductor substrate having a second dopant, and a third region in the semiconductor substrate having the first dopant. A first light absorption layer is on the surface and over a fourth region of the semiconductor substrate between the first and second regions. The first light absorption layer is configured to absorb light of a particular wavelength. A second light absorption layer is on the surface and over a fifth region of the semiconductor substrate between the second and third regions. The second light absorption layer is configured to absorb the light of the particular wavelength. At least one of respective lateral dimensions of the first and second light absorption layers or a lateral separation between the first and second light absorption layers is based on the particular wavelength.

In another example, a semiconductor device includes a semiconductor substrate having a surface, a first region in the semiconductor substrate having a first dopant, a second region in the semiconductor substrate having a second dopant and a third region in the semiconductor substrate having the first dopant. The semiconductor device also includes an array of light absorption regions on the surface.

In yet another example, a light detection circuit includes a light detector having a semiconductor substrate having a surface, a first region in the semiconductor substrate having a first dopant, a second region in the semiconductor substrate having a second dopant, a third region in the semiconductor substrate having the first dopant, and an array of light absorption regions on the surface. The light detection circuit also includes a bias circuit coupled to the first and second terminals.

### BRIEF DESCRIPTION OF THE DRAWINGS

FIG. 1 is a cross-sectional view of a light detector having a continuous absorption layer, in an example.

FIG. 2 is a cross-sectional view of a light detector having an absorption layer which includes an array of light absorption regions, in an example.

FIG. 3 is a schematic diagram illustrating a photon of light passing through absorption regions and reflecting off interfaces between the absorption region and an adjacent dielectric material, in an example.

FIG. 4 is a top view of the light detector of FIG. 2 in which the array of light absorption regions is a one-dimensional array, in an example.

FIG. 5 is a top view of the light detector of FIG. 2 in which the array of light absorption regions is a two-dimensional array, in an example.

FIG. 6 are graphs illustrating the index of absorption at varying wavelengths of light for light detectors having arrays of light absorption regions and light detectors having continuous absorption layers, in an example.

FIG. 7 is a cross-sectional view of an example of light detector having an array of light absorption regions and an avalanche photodiode, in an example.

FIG. 8 is a top view of the light detector of FIG. 8, in an example.

FIG. 9 is a circuit in which a light detector having an array of light absorption regions can be used.

### DETAILED DESCRIPTION

The same reference numbers or other reference designators are used in the drawings to designate the same or similar (either by function and/or structure) features.

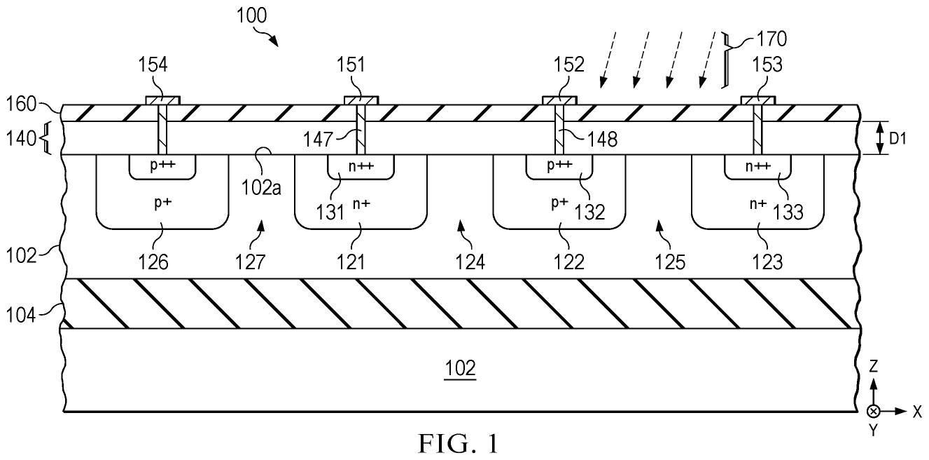

FIG. 1 is a cross-sectional view of a light detector 100, in an example. Light detector 100 includes a semiconductor substrate 102. Semiconductor substrate 102 can include, for example, p-doped or n-doped silicon or another suitable material. In the example of FIG. 1, a buried dielectric layer 104 is formed in semiconductor substrate 102. The buried dielectric layer 104 may be silicon oxide or another suitable dielectric material.

Light detector 100 also includes a first region 121, a second region 122, and a third region 123. The first, second, and third regions 121, 122, and 123 are in semiconductor substrate 102. The first and third regions 121 and 123 have a first dopant, and the second region 122 has a second dopant. In one example, the first dopant is of a type (e.g., phosphorus, arsenic) that increases the number of mobile negative charge carriers (electrons) within the corresponding region. The second dopant is of a type (e.g., boron) that increases the number of mobile positive charge carriers (holes) within the corresponding region. The first and third regions 121 and 123 may be N-type silicon, and the second region 122 may be P-type silicon. First and second regions 121 have portions 131 and 133 that have a higher dopant concentration (as indicated by the designation “N++”) than the surrounding portion (N-type). Similarly, the second region 122 has a portion 132 that has a higher dopant concentration (as indicated by the designation “P++”) than the surrounding portion (P-type). A region 124 of semiconductor substrate 102 is between regions 121 and 122. A region 125 of semiconductor substrate 102 is between regions 122 and 123. The example cross-sectional view of FIG. 1 also includes a sixth region 126 (P-type) separated along the x-axis from region 121 by a region 127 of semiconductor substrate 102. Light detector 100 can have multiple P-type regions such regions 122 and 126 and multiple n-type regions such as regions 121 and 123. P-type region 122 and N-type region 121 form a PN junction.

Semiconductor substrate 102 has a surface 102a. Light detector 100 includes a light continuous absorption layer 140 on the surface 102a of semiconductor substrate 102. A protective dielectric layer 160 (e.g., silicon dioxide) can cover continuous absorption layer 140. Electrically conductive vias 147 and 148 provide electrical connectivity between corresponding terminals 151 and 152 and the respective regions 121 and 122. Terminal 151 may be a cathode, and terminal 152 may be an anode. Similarly, terminals 153 (cathode) and 154 (anode) may be coupled to regions 123 and 124, respectively. Terminals 151 and 153 may be coupled together and terminals 152 and 154 may be coupled together. A bias voltage can be applied between the cathode terminal (e.g., terminals 151, 153) and the anode terminal (e.g., terminals 152, 154) such that the voltage at the cathode terminal 151, 153 is more positive than the voltage at the anode terminal 152, 154 thereby reverse-biasing the PN junction formed by p-type second region 122 and n-type first region 121. The reverse-biased PN junction creates an electric field which permeates absorption layer 140.

Photons 170 of light may pass through dielectric layer 160 and enter light absorption layer 140. Any given photon 170 of light may pass through light absorption layer 140 or be absorbed by light absorption layer 140. If the photon 170 is absorbed by light absorption layer 140, an electron-hole pair can be created in the light absorption layer. The electric field created by the voltage difference between the cathode and anode causes the electron to separate from the hole. As more and more electron-hole pairs are created by photons in light absorption region 140, a current develops between terminals 151 and 152. The magnitude of the current is a function of the intensity of the light received by light detector 100.

The material forming light absorption layer 140 may depend on the wavelength of light to which light detector 100 is intended to be sensitive. For example, absorption layer 140 may include germanium (Ge) which may absorb light having a wavelength in the range of approximately 1200 nm to 1600 nm. In another example, the absorption layer 140 may include silicon which can absorb light having wavelengths in the range of 400 nm to 1100 nm.

The thickness of light absorption layer 140 is D1. Light absorption layer 140 is a thin film meaning that D1 is relatively small. In one example, D1 is less than 1000 nm, which is substantially smaller than the wavelength of light to which the light detector is intended to be sensitive (e.g., 1200 nm to 1600 nm). Because the thickness D1 of light absorption layer 140 is substantially smaller than the wavelength of light to be detected, light absorption layer 140 may not absorb a significant amount of light and too few photons create electron-hole pairs to result in a significant level of current. Accordingly, the responsivity of light detector 100 with its continuous light absorption layer 140 is relatively low.

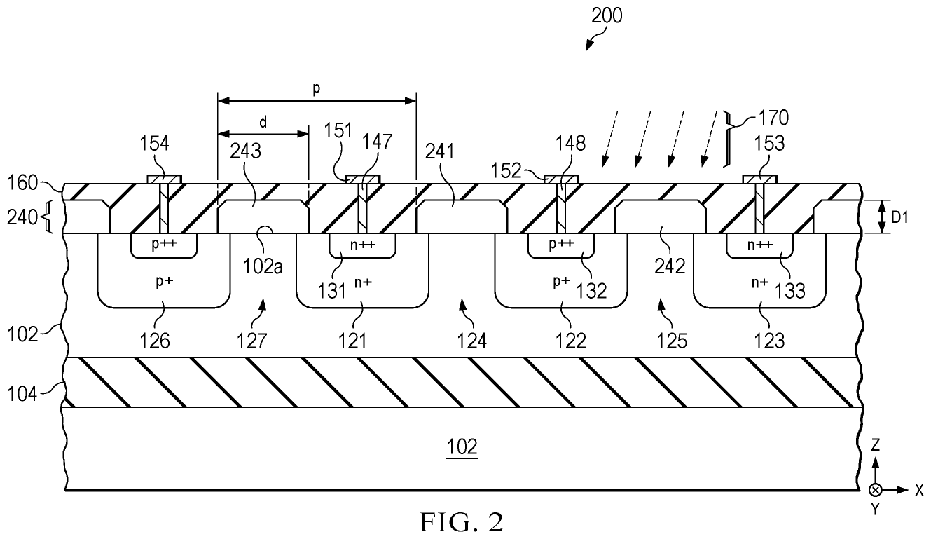

FIG. 2 is a cross-sectional view of a light detector 200, in an example. Light detector 200 includes the semiconductor substrate 102, dielectric layer 104, regions 121, 122, 123, and 126 and electrically conductive vias (e.g., vias 147 and 148) coupled between the regions 121, 122, 123, and 126 and the respective terminals 151, 152, 153, and 154. Terminals 151 and 153 are cathode terminals in this example, and terminals 152 and 154 are anode terminals.

Instead of a continuous absorption layer 140 as in the light detector 100 of FIG. 1, light detector 200 in FIG. 2 includes an array 240 of light absorption regions (also referred to as layers) 241, 242, and 243. The array 240 of light absorption regions 241-243 is on surface 102a of semiconductor substrate 102. Light absorption layer 241 is on surface 102a and over region 124 of semiconductor substrate 102 between regions 121 and 122. Light absorption layer 242 is on surface 102a and over region 125 between regions 122 and 123. Similarly, light absorption layer 243 is on surface 102a and over region 127.

Each light absorption region 241-243 may include germanium, silicon, a III-V compound, or a II-VI compound. Examples of III-V compounds include GaAs and InGaAsP. Examples of II-VI compounds include ZnSe and WSe₂. The type of material used for the light absorption regions is based on the particular wavelength of light for which the light detector is intended to be sensitive. For example, light absorption regions 241-243 may include germanium for detecting light having wavelengths in the range of 1200 nm to 1600 nm or silicon for detecting light having wavelengths in the range of 400 nm to 1100 nm.

The thickness D1 of light absorption regions 241-243 may be less than 1000 nm, which is substantially less than the wavelength of light to which light detector 200 is sensitive. The diameter of each light absorption region 241-243 is d and the pitch of the array 240 is p. The array of light absorption regions 241-243 of light detector 200 of FIG. 2 creates cavities in which more light can be absorbed than for the continuous absorption layer 140 of light detector 100 of FIG. 1. Light from any given light absorption region 241-243 destructively interferes with neighboring light absorption regions to thereby form cavities with a particular quality factor Q indicating how much light can be absorbed in a cavity. The quality factor Q is a function of the ratio of the diameter d to pitch p of the array 240. The larger the number of light absorption regions 241-243 in the array 240, the larger will be the quality factor Q. Because the photons collect in the light absorption regions 241-243, the likelihood is greater that electron-hole pairs are created. Accordingly, the current produced by light detector 200 with its array of light absorption regions is greater than the current produced by light detector 100 with its continuous light absorption layer, all else being equal.

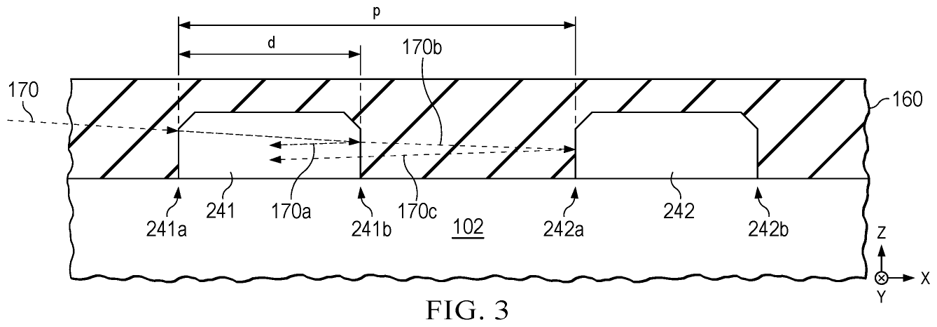

FIG. 3 is a cross-sectional view of light detector 200 showing regions 241 and 242. A possible path of light 170 is illustrated as entering light absorption region 241 at interface 241a between the light absorption region and dielectric layer 160. Due to the refraction indices of light absorption regions 241/242 being higher than the refractive index of the dielectric layer 160, some of light 170 can be reflected at interface 241b as 170a, and some of light 170 can pass through interface 241b and reach interface 242a as light 170b. Some of light 170b can be reflected at interface 242a and propagate back into light absorption region 241 as 170c. The pitch (p) between adjacent light absorption layers (e.g., 241 and 242) and the lateral width (d) of each light absorption layer can be configured such that there is destructive interference between light 170b and 170c to reduce the power of light that radiates away from a light absorption layer (e.g., 240), and to retain the reflected light (e.g., light 170a) for an increased duration to facilitate absorption. Accordingly, a pattern of areas with different refractive indices can cause the incoming electromagnetic wave (light 170) to be confined in high refractive index semiconductor (absorption layer) cavities.

In some examples, the width d of each light absorption region 241-243 and the pitch p of the array of light absorption regions is set based on the wavelength of light to which light detector 200 is to be sensitive. For example, for a value of d and p of approximately 800 nm and 1000 nm, respectively, and using germanium to form light absorption regions 241, 242, and 243, light detector 200 with an array of light absorption regions 241-243 may have a range of operation from 1200 to 1600 nm.

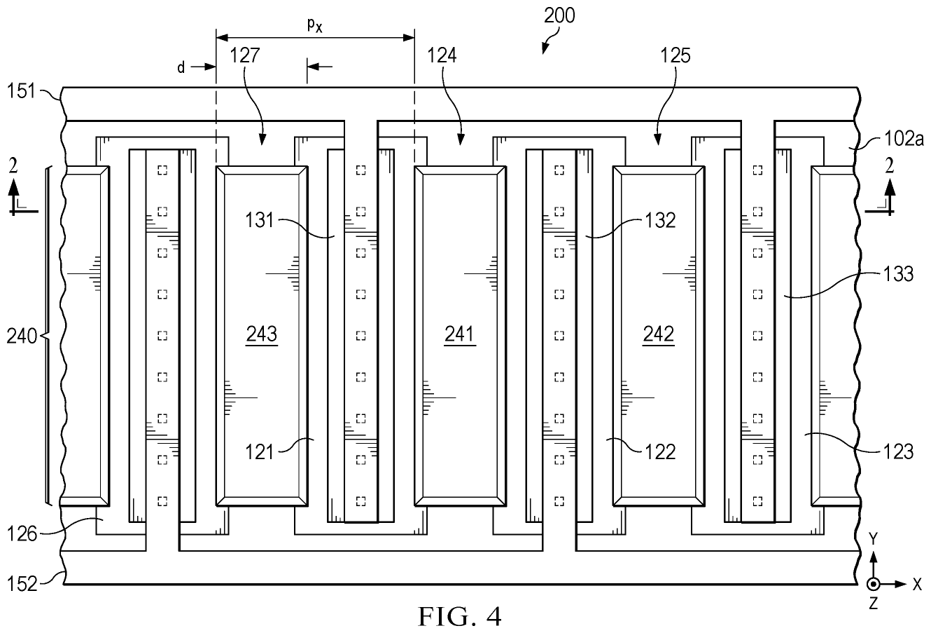

FIG. 4 is a top view of light detector 200. Regions 121, 122, 123, and 126 extend laterally along the y-axis on surface 102a of semiconductor substrate 102. Region 122 is laterally between regions 121 and 123 along the x-axis, which is orthogonal to the y-axis. Similarly, region 121 is laterally between regions 126 and 122 along the x-axis. In FIG. 4, the array 240 of light absorption regions 242-243 is a one-dimensional array extending along the x-axis. Light absorption region 241 is laterally between light absorption regions 242 and 243. The polarization of light includes transverse electric (horizontal) polarization and transverse magnetic (vertical) polarization. Depending on the incident angle of light into the one-dimensional array of light absorption regions 241-243, one polarization type or the other will be dominant as for the absorption of the light.

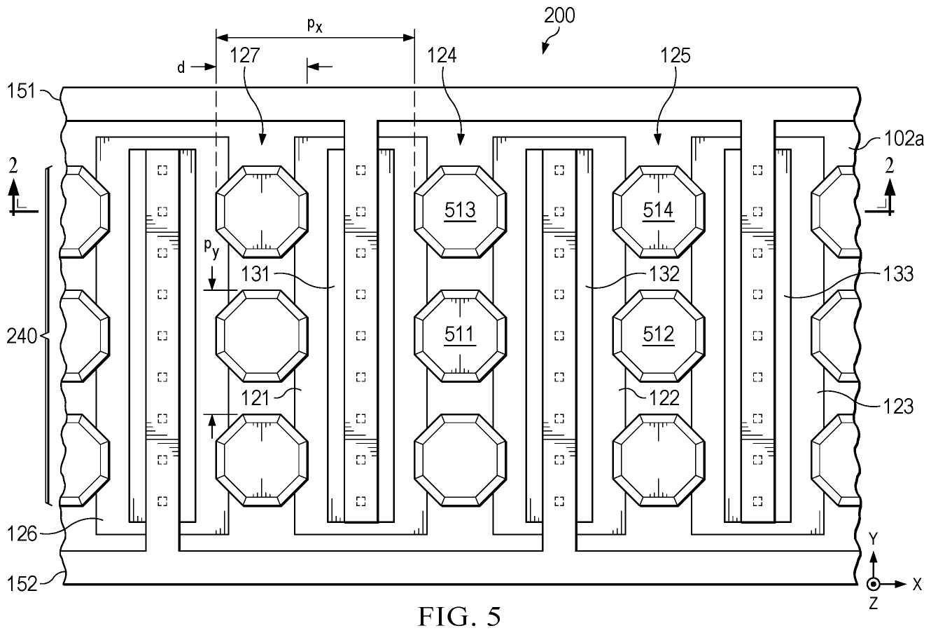

FIG. 5 is a top view of light detector 200 in another example in which the array 240 of light absorption regions is a two-dimensional array. The array 240 of light absorption regions in the example of FIG. 5 includes, for example, light absorption regions 511, 512, 513, and 514, all of which are over surface 102a of semiconductor substrate 102. Light absorption regions 511 and 513 are over region 124 of semiconductor substrate 102. Light absorption regions 512 and 514 are over region 125 of semiconductor substrate 102.

In the example of FIG. 5, each light absorption region 511-514 includes a circular pillar. The diameter d of the pillars is the same among all of the light absorption regions 511-514. In other examples, the diameter d of one or more of the light absorption regions 511-514 is different than the diameter d of one or more of the other light absorption regions 511-514. Further, the shape of each pillar can be other than circular in other examples. For example, the shape of each pillar may be square, rectangular, elliptical, etc. The pitch of the array is denoted by pₓ along the x-axis and p_{y} along the y-axis. In some examples, pₓ is equal to p_{y}. In other examples, pₓ is not equal to p_{y}. Having pₓ equal to p_{y} results in cavities that absorb a large amount of light but in a narrow bandwidth as shown in 610 in FIG. 5 (described below). Having pₓ different than p_{y} may result in cavities absorbing less light than when pₓ equals p_{y} due to incomplete cancellation of interferences in neighboring blocks but with a wider bandwidth absorption/responsivity performance.

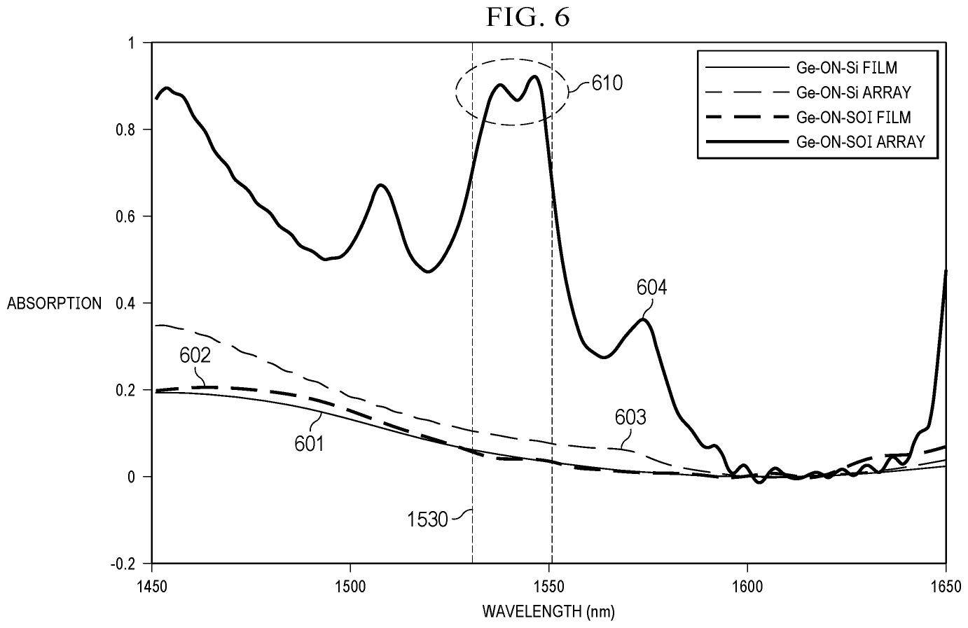

FIG. 6 is a graph of the coefficient of absorption of the light absorption layer relative wavelength of light. Curve 601 represents the coefficient of absorption for a continuous layer of germanium on a silicon substrate 102 without a buried dielectric layer 104. Curve 602 represents the coefficient of absorption for a continuous layer of germanium on a silicon substrate 102 with a buried dielectric layer 104. Curve 602 corresponds to the light detector 100 of FIG. 1. Curve 603 represents the coefficient of absorption for an array of germanium-based light absorption regions on a silicon substrate 102 without a buried dielectric layer 104. Curve 604 represents the coefficient of absorption for an array of germanium-based light absorption regions on a silicon substrate 102 with a buried dielectric layer 104. Curve 604 corresponds to the light detector 200 described above. For wavelengths in the range of approximately 1530 nm to 1550 nm, curves 603 and 604 have a higher index of absorption than curves 601 and 602. Accordingly, a light detector 200 having an array of light absorption regions has a higher index of absorption, especially if the silicon substrate includes a buried dielectric layer 104, than for a light detector having a continuous layer of light absorption material. For example, the index of absorption for curve 604 is approximately 0.9 as indicated by reference numeral 610 at a wavelength in the range of 1530 to 1550 nm while the index of absorption for curves 601 and 602 is approximately 0.1 for the same range of wavelengths. Accordingly, a light detector having an array of light absorption regions may have a higher responsivity than a light detector having a continuous layer of light absorption material.

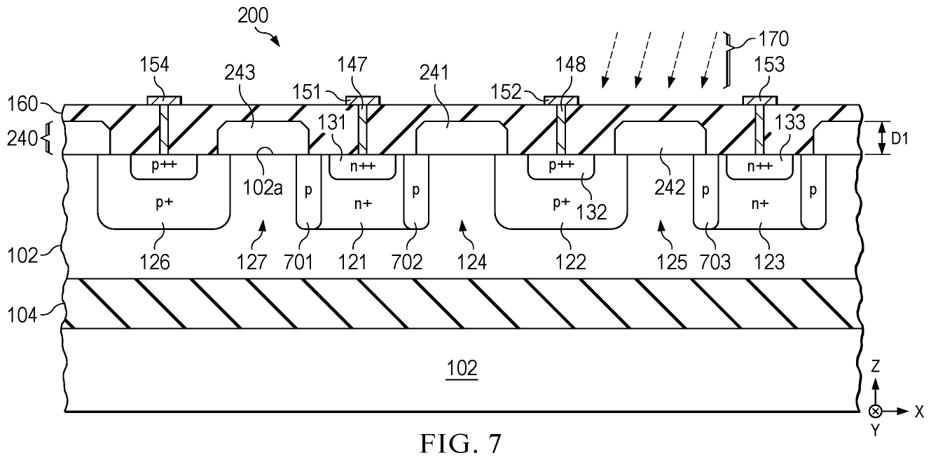

FIG. 7 is a cross-sectional view of an example of light detector 200 implementing an avalanche photodiode. The structure of FIG. 7 is largely the same as the structure of FIG. 2. A difference is the inclusion of regions 701, 702, and 703 forming multiplication regions. In this example, regions 701, 702, and 703 have a P-type dopant. P-type region 702 and N-type region 121 form a PN junction. Similarly, P-type region 702 and N-type region 121 form a PN junction, and P-type region 703 and N-type region 123 form another PN junction. As electron-hole pairs are formed in absorption regions 241, 242, and 243, electrons separate from the holes and enter the P-type regions 701, 702, and 703 where the electrons create additional electron-hole pairs through impact ionization. In another example, N-type regions may be formed adjacent to the p+ regions 122, 126 of the anodes to form the APD multiplication regions.

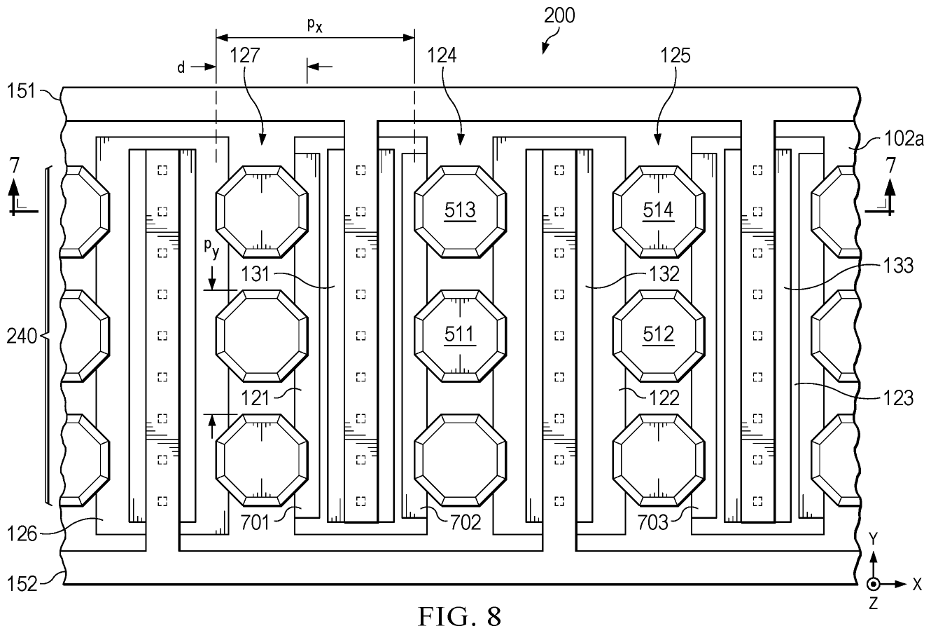

FIG. 8 is a top view of the light detector 200 of FIG. 8 illustrating P-type regions 701, 702, and 703 extending laterally along the Y-axis.

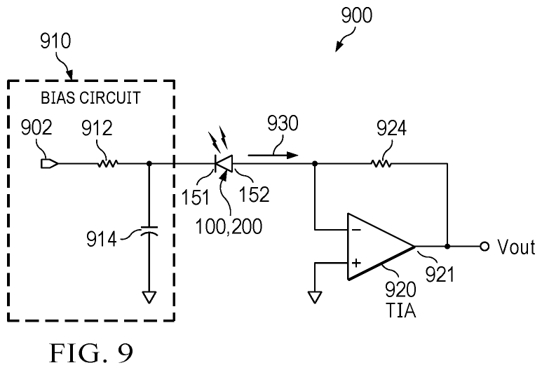

FIG. 9 is a schematic diagram of a circuit 900 which includes a bias circuit 910, a light detector 100 or 200, a transimpedance amplifier (TIA) 1020, and a resistor 924. In this example, bias circuit 910 includes a resistor 912 coupled to a capacitor 1014. Resistor 912 is coupled between a voltage input terminal 902 and the cathode 151 of the light detector 100, 200. Capacitor 914 is coupled between the cathode 151 and ground. The negative input of TIA 920 is coupled to the anode 152 of the light detector 100, 200. Resistor 924 is coupled between the negative input of TIA 920 and the output 921 of TIA 920.

The resistor 912 and capacitor 914 of the bias circuit 910 form a low-pass filter to filter out higher frequency (e.g., noise) of a voltage at the voltage input terminal 920. Bias circuit 910 provides the filtered voltage from the voltage input terminal 902 to the cathode 151 of light detector 100, 200 The positive terminal of TIA 920 is coupled to ground, and accordingly, the negative terminal of TIA 920 also is at the ground potential. Because the anode 152 of the light detector 100, 200 is at the ground potential and the cathode 151 is at the voltage of the voltage input terminal 902, light detector 100, 200 is reverse-biased.

Light detector 100, 200 produces a current 930 based on the intensity of the light it receives. The TIA 920 converts the current 930 from light detector 100, 200 to a voltage (Vout) at the output 921. The voltage Vout is given as: Vout=−(R924 *I930), where R924 is the resistance of resistor 4924 and I930 is the magnitude of current 930.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A semiconductor device, comprising:
a semiconductor substrate having a surface;
a first region in the semiconductor substrate having a first dopant;
a second region in the semiconductor substrate having a second dopant;
a third region in the semiconductor substrate having the first dopant;
a first light absorption layer on the surface and over a fourth region of the semiconductor substrate between the first and second regions, the first light absorption layer configured to absorb light of a particular wavelength; and
a second light absorption layer on the surface and over a fifth region of the semiconductor substrate between the second and third regions, the second light absorption layer configured to absorb the light of the particular wavelength, in which at least one of respective lateral dimensions of the first and second light absorption layers or a lateral separation between the first and second light absorption layers is based on the particular wavelength.

2. The semiconductor device of claim 1, wherein:
each region of the first, second, and third regions extends laterally along a first axis on the surface;
the second region is laterally between the first and third regions along a second axis on the surface; and
the second axis is orthogonal to the first axis.

3. The semiconductor device of claim 2, further comprising an array of light absorption layers including the first light absorption layer and the second light absorption layer.

4. The semiconductor device of claim 3, wherein the array is a one-dimensional array extending along the first axis.

5. The semiconductor device of claim 3, wherein:
the array is a two-dimensional array comprising a third light absorption layer and a fourth light absorption layer;
the third light absorption layer is on the surface and is over the fourth region of the semiconductor substrate; and
the fourth light absorption layer is on the surface and is over the fifth region of the semiconductor substrate.

6. The semiconductor device of claim 5, wherein each light absorption layer of the first, second, third, and fourth light absorption layers comprises a circular pillar.

7. The semiconductor device of claim 5, wherein the first light absorption layer has a different shape than the second light absorption layer.

8. The semiconductor device of claim 5, wherein the first light absorption layer has a different dimension than the second light absorption layer.

9. The semiconductor device of claim 5, wherein the first and second light absorption layers are separated by a first distance, and the third and fourth light absorption layers are separated by a second distance.

10. The semiconductor device of claim 1, wherein the first and second light absorption layers comprise at least one of germanium, silicon, a III-V compound, and II-VI compound.

11. The semiconductor device of claim 1, further comprising a sixth region between the first region and the fourth region, wherein:
the first dopant is an n+ dopant;
the first region has a portion that has an n++ dopant;
the second dopant is a p+ dopant; and
the sixth region has a p-type dopant.

12. The semiconductor device of claim 1, further comprising:
a first electrical terminal coupled to first region configured as a cathode; and
a second electrical terminal coupled to the second region configured as an anode.

13. A semiconductor device, comprising:
a semiconductor substrate having a surface;
a first region in the semiconductor substrate having a first dopant;
a second region in the semiconductor substrate having a second dopant;
a third region in the semiconductor substrate having the first dopant; and
an array of light absorption regions on the surface.

14. The semiconductor device of claim 13, wherein the array is a one-dimensional array.

15. The semiconductor device of claim 13, wherein the array is a two-dimensional array.

16. The semiconductor device of claim 13, wherein the substrate includes a buried silicon-oxide layer.

17. The semiconductor device of claim 13, wherein the semiconductor device is a light detector.

18. A light detection circuit, comprising:
a light detector having a semiconductor substrate having a surface, a first region in the semiconductor substrate having a first dopant, a second region in the semiconductor substrate having a second dopant, a third region in the semiconductor substrate having the first dopant, and an array of light absorption regions on the surface; and
a bias circuit coupled to the first and second terminals.

19. The light detection circuit of claim 18, wherein the array is a two-dimensional array.

20. The light detection circuit of claim 18, further comprising a fourth region adjacent the first region and between the first region and the second region, wherein:
the first dopant is an n+ dopant;
the second dopant is a p+ dopant; and
the fourth region is a p-type dopant.
